(19) United States
(12) Patent Application Publication
(10) Pub. No.: US 2008/0305244 A1
(43) Pub. Date: Dec. 11, 2008

(54) MONITORING A COATING APPLIED TO A METAL SURFACE

(76) Inventors: Ji Cui, Naperville, IL (US); Rodney H. Banks, Aurora, IL (US)

Correspondence Address: Peter A. DiMattia;Patent and Licensing Department, Nalco Company, 1601 West Diehl Road, Naperville, IL, 60563-1198, US

(21) Appl. No.: 11/760,029

(22) Filed: Jun. 8, 2007

(51) Int. Cl. C23C 16/52

(52) U.S. Cl. 427/9

(57) ABSTRACT

A method of monitoring a coating applied to a metal surface is disclosed. Specifically, the method comprises the following: applying a sol composition to a metal surface, wherein said composition contains one or more alkoxysilyl group containing compounds, a fluorophore, and a solvent; forming a gelled coating on said surface from said composition; measuring the fluorescence of said coating with a fluorometer, wherein said fluorometer is capable of measuring reflective fluorescence emission measurements; correlating the fluorescence of said coating with the thickness or weight of said coating, and/or with the concentration of alkoxysilyl group containing compound in the coating composition; and optionally applying an additional coating to said metal surface when the thickness of the coating is less than a desired amount or adjusting the concentration of the alkoxysilyl group containing compound applied to said surface.

### BACKGROUND OF THE INVENTION

Detection of a coating, e.g. a pretreatment coating, applied to a metal surface is useful to one of ordinary skill in the art in a finishing industry because it allows for quality control of the pretreated metal surface.

Because coatings used on metal surfaces impart many properties to a metal surface, including, but not limited to, inhibiting/reducing the rate of corrosion on the metal surface, and improving paint adhesion to the metal surface, the importance of making sure the coating composition is properly applied is of utmost importance to the finishing industry.

Many coating compositions used in the industry contain either chromate or non-chromate containing compositions.

Chromate-containing compositions are easy to detect because chromate treatment of a metal surface imparts a strongly iridescent yellow tint on the metal surface.

Many non-chromate containing coatings are not easy to detect because they produce thin films that are either colorless or only slightly colored.

Therefore, there is a need in the industry for a method of detecting non-chromate containing coatings, e.g. pretreatments films, which are applied to metal surfaces.

### SUMMARY OF THE INVENTION

This disclosure pertains to a method of monitoring a coating applied to a metal surface comprising applying a sol composition to a metal surface, wherein said composition contains one or more alkoxysilyl group containing compounds, a fluorophore, and a solvent; forming a gelled coating on said surface from said composition; measuring the fluorescence of said coating with a fluorometer, wherein said fluorometer is capable of measuring reflective fluorescence emission measurements; correlating the fluorescence of said coating with the thickness or weight of said coating, and/or with the concentration of alkoxysilyl group containing compound in the coating composition; and optionally applying an additional coating to said metal surface when the thickness of the coating is less than a desired amount or adjusting the concentration of the alkoxysilyl group containing compound applied to said surface.

### FIGURES

FIG. 1 illustrates a reflectance-based fluorometer with an angled configuration.

FIG. 2 illustrates a reflectance-based fluorometer with a collinear configuration.

FIG. 3 shows the fluorescence emission profile of traced coatings with various concentrations.

FIG. 4 shows the fluorescent signal of traced coatings as a function of concentration.

FIG. 5 shows the fluorescent signal of the traced coatings as a function of thickness.

### DETAILED DESCRIPTION OF THE INVENTION

A sol composition is applied to a metal surface. The sol containing composition contains an alkoxysilyl compound.

In one embodiment, the alkoxysilyl compound comprises a monofunctional silane and/or a multifunctional silane.

In another embodiment, the alkoxysilyl compound is monomeric or polymeric.

In another embodiment, the alkoxysilyl compound is hydrolyzed or unhydrolyzed.

Various types of alkoxysilyl compounds may be utilized for this invention. They include: TECHBOND 38513, TECHBOND 38514, both commercially available from Nalco Company, and their derivatives. U.S. Pat. No. 6,867,318 describes these compounds and is herein incorporated by reference.

One alkoxysilyl group containing compound described in U.S. Pat. No. 6,867,318 comprises a composition of matter of formula:

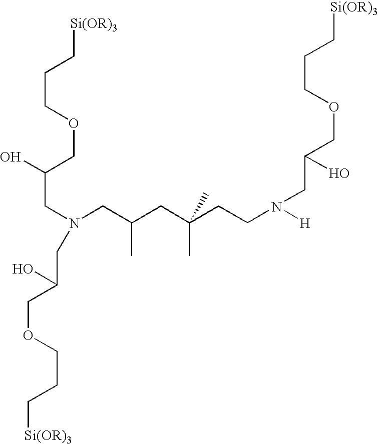

where R is H or C₁-C₆ alkyl. A preferred composition is when R is methyl.

Another alkoxysilyl group containing compound described in U.S. Pat. No. 6,867,318 comprises a composition of matter of formula:

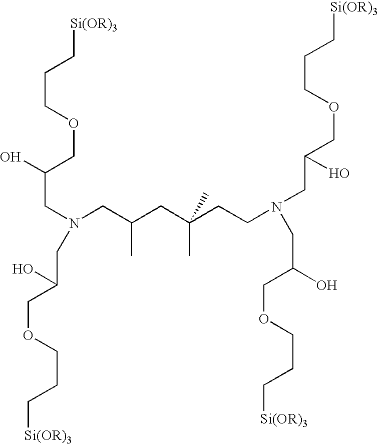

where R is H or C₁-C₆ alkyl. A preferred composition is when R is methyl.

An effective amount of alkoxysilyl group is added to the sol composition. The effective amount is an amount that will provide adequate corrosion protection and adherence to the metal surface. In one embodiment, the composition contains at least 0.1% by weight of said alkoxysilyl group containing compound relative to the composition.

A fluorophore is also added to the composition applied to a metal surface.

Various types of fluorophores can be utilized. A fluorophore has the ability to fluoresce in a given medium, particularly in this case, a gelled composition applied to a metal surface. One of ordinary skill in the art would be able to determine which fluorophore to use without undue experimentation. For example, the metal surface may affect fluorescence of a given fluorescent molecule.

In one embodiment the fluorophore is selected from the group consisting of: pyrenetetrasulfonate, fluorescein, rhodamine, and derivatives thereof.

The amount of fluorophore depends upon several factors that would be apparent to one of ordinary skill in the art, such as interference, e.g. quenching, from other molecules in the system, composition makeup, sensitivity of the fluorometer, quantum efficiency of the fluorophore, and excitation and emission wavelengths of the fluorophore.

In one embodiment, the composition contains from about 20 ppb to 20,000 ppm of said fluorophore, relative to alkoxysilyl group containing compound by weight.

In another embodiment, the composition contains from about 10 ppm to about 1000 ppm of said fluorophore, relative to alkoxysilyl group containing compound by weight.

The composition is applied to a metal surface. The metal surface may consist of one or more types of metals.

In one embodiment, the metal is selected from the group consisting of: aluminum, tin, steel, zinc, titanium, nickel, copper, alloys thereof, and a combination thereof.

One or more steps are taken to gel the sol composition so that a gelled coating forms on the metal surface. For example, the coating is cured so that the sol molecules cross-link into a dense solid matrix.

The fluorescence of the gelled composition is then measured by a reflectance fluorometer.

Fluorescence of the coating can be measured by reflectance methods known in the art. For ease of use the fluorometer is a handheld device that can be placed over a portion of the coated area to take a reading. The reflectance fluorometer typically uses a light source that projects an excitation beam of light onto the coating causing the added tracer to fluoresce at an intensity that can be measured. The fluorometer also contains a detector assembly that can suitably detect the fluorescence emission while rejecting scattered excitation light.

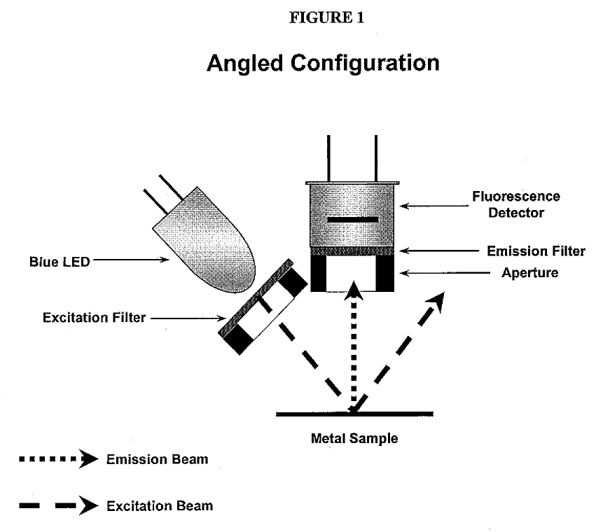

Application of a coating on a metal surface requires that the fluorescence be measured by reflectance. In common fluorometry of aqueous solutions, fluorescence is detected at right angles to the excitation beam in order to minimize interference due to excitation light. In reflectance fluorometry, this configuration cannot be used due to the reflecting metal substrate and thin coating. In order to reduce scattered light interference, the excitation beam can be projected onto the sample at an oblique angle whereby the reflected excitation is directed away from the detector's field of view. Fluorescence emission emanates at all angles some of which is captured by the detector. FIG. 1 shows a simple depiction of the optical arrangement.

In one embodiment, a blue LED (LEDtronics) fitted with a bandpass filter at 470 nm (Omega Optical) and ring collimator is mounted to project a beam at approximately a 45° angle with respect to the surface of the metal. The fluorescence detector is mounted perpendicularly to the metal surface and is fitted with a collimator and bandpass filter allowing 515 nm light to pass through. It is seen that the intense reflected excitation beam bypasses the detector whereas the fluorescence is detected. The optical detector is any silicon photodiode such as that manufactured by Hamamatsu Corporation.

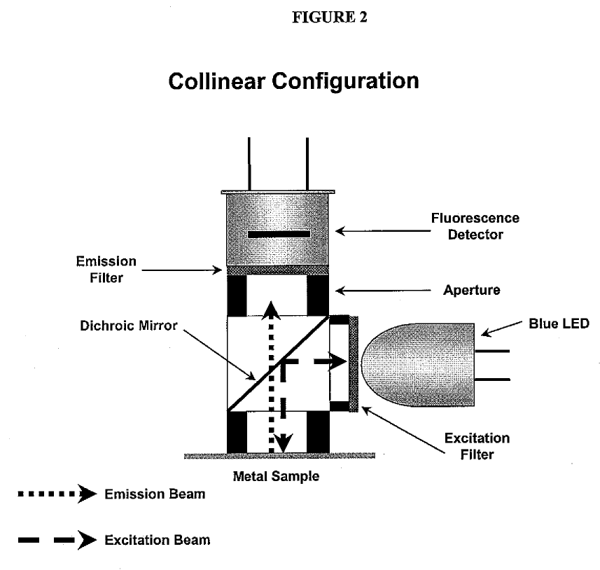

A second optical configuration that can be used is commonly found in confocal fluorescence microscopes in which the excitation and emission beams are collinear. This configuration requires an additional optical element, a dichroic filter. A diagram of the configuration is shown in FIG. 2.

In this configuration, the filtered excitation beam is reflected at a right angle onto the sample surface by a dichroic filter (Omega Optical), which has the property of reflecting the excitation wavelength while transmitting the emission wavelength. Therefore, the reflected excitation beam is reflected back into the LED source and away from the detector. The fluorescence emission is transmitted to the detector and filter assembly.

In both configurations, the basic source intensity can optionally be measured to provide a correction to source intensity drift and LED aging. This can be accomplished by mounting a second photodiode (not shown) next to the LED tip to detect scattered light that is proportional to the light source intensity.

Those skilled in the art can incorporate the electronic circuitry to power the LED and amplify the photodiode current to a measurable voltage.

Correlating fluorescence with the thickness or weight of the applied coating can be determined by one ordinary skill in the art without undue experimentation.

The intensity of the measured fluorescence is converted to coating thickness through a calibration curve. More specifically, a linear calibration curve can be derived from measured data from an uncoated metal surface as the zero point and the voltage from a traced coating of known thickness.

After determining the thickness of the coating, the amount of coating can be adjusted to comport with a given specification.

Correlating fluorescence with the concentration of alkoxysilyl compound can also be determined by one of ordinary skill in the art without undue experimentation. More specifically, by knowing the ratio of both the fluorophore and alkoxysilyl compound added to the composition applied to the metal surface, then the concentration of the alkoxysilyl compound can be calculated based upon the amount of fluorophore, which is determined by fluorescence.

After determining the concentration of the alkoxysilyl compound in the coating, the amount of alkoxysilyl compound in the coating can be adjusted to comport with a given specification.

The following examples are not meant to be limiting.

### EXAMPLES

### Example 1

A water soluble silane concentrate, a TECHBOND® 38514 concentrate, was charged with a small amount of fluorescein dye so that the fluorescein content in the total solid was 200 ppm. This dye-traced concentrate was thoroughly mixed and diluted in water to make 1.0%, 2.0%, 3.0%, 4.0%, 5.0% by weight of use solutions. TECHBOND 38514 instantly and spontaneously hydrolyzes and polymerizes upon dilution in water. Meanwhile, an aluminum panel was degreased with an alkaline cleaner Globrite 45IL, available from Nalco Company, and then the panel was coated with the aqueous sol solutions of TECHBOND 38514. The coatings were baked until dry. The handheld, reflectance fluorometer was placed on an uncoated metal sample and zeroed. Each sample was read and its emission spectrum recorded after subtracting the blank. Because film thicknesses of the gelled films are proportional to the concentration of sol solutions from which they are derived, the reading of the reflectance fluorometer correlates to both film thickness and concentration of the sol solution.

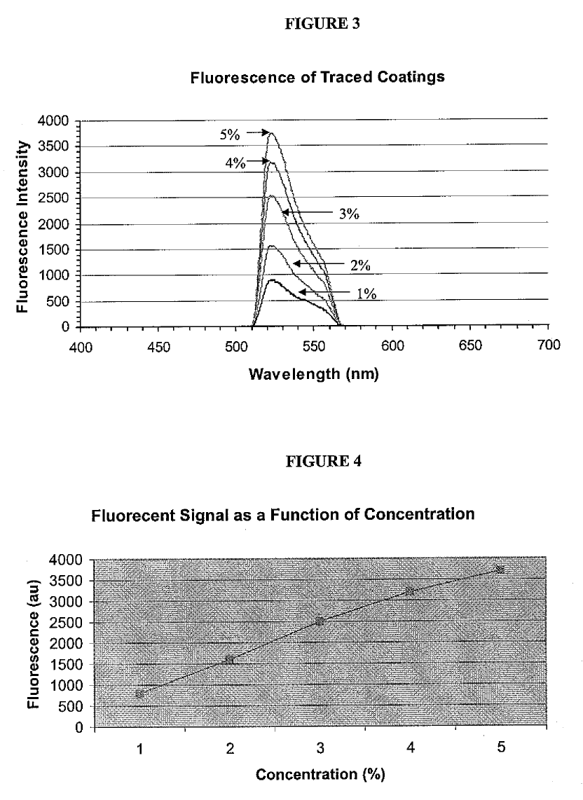

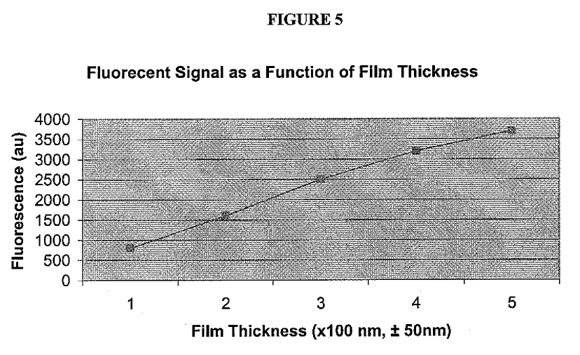

The signal of the detected fluorescence as a function of use solution concentration is shown in the following FIG. 3. A plot of fluorescence peak signal strength as a function of concentration is also shown (working curve). In this way, the fluorescence reading of a pretreatment coating directly translates to the coating solution concentration or film thickness by reading from the working curve, shown in FIG. 4 and FIG. 5, respectively. This is particularly useful for nonchrome pretreatments whose concentration cannot be determined by conventional titration methods. Furthermore, if one also knows the relationship of coating weight and solution concentration, the fluorescence signal strength will also relate to coating weight. All these relations depend on one critical factor—the fixed known dye-to-silane ratio, which is fixed at 200 ppm in these examples.

### Example 2

This example illustrates the effect of metal substrates on the fluorescent signal of different dyes.

Five metal substrates were chosen in this example: cold-rolled steel, galvanized steel, galvalum steel, tinplated steel, and aluminum. In addition, five different dyes were picked to cover a wide range of emission spectra. The five dyes were the following: pyrenetetrasulfonic acid sodium salt (PTSA), fluorescein, Alexa Fluor 660 (available from Molecular Probes), sulfo-rhodamine, and rhodamine.

Nalco Techbond 38513, a water-soluble silane, was prepared in water to a 2% solid. The resulting solution was mixed with each of the five dyes so that the dye content in the total solid was 200 ppm (or 4 ppm in the solution).

The metal substrates were punched into 1 inch diameter wafers and were degreased with Globrite 45IL alkaline cleaner at 120° F. for 1 minute. Coated metal wafers were then prepared by dip-coating them in the prepared solutions. The metal wafers were then oven baked at 190° F. for 5 minutes to crosslink (gel) the silane film.

The fluorescence of the coated metal surface was then measured by using a handheld, reflectance based fluorometer. The fluorometer was placed on an uncoated metal sample and zeroed. Each sample was read and its emission spectrum recorded after subtracting the blank.

Table 1 shows the fluorescence of different dyes on different metal substrates. The numbers in parentheses are the emission wavelengths and the numbers in the body of the table are the maximum emission intensities as detected by the fluorometer.

It appears that the optimal emission wavelength of the fluorophores lies in the 450-750 nm range, and virtually no fluorescence was detected for PTSA (which emits at 400-450 nm) on all substrates.

TABLE 1

| | Fe | Al | Zn | Sn | Al—Zn |
|---|---|---|---|---|---|
| Alexa Fluor 660 (697–712 nm) | 201 | 432 | 0 | 79 | 0 |
| Sulfo Rhodamine (598–601 nm) | 320 | 1024 | 317 | 523 | 618 |
| Rhodamine (560–573 nm) | 765 | 3014 | 555 | 143 | 579 |
| PTSA (400–450 nm) | 0 | 0 | 0 | 0 | 0 |
| Fluorescein (525 nm) | 310 | 650 | 310 | 320 | 400 |

1. A method of monitoring a coating applied to a metal surface comprising:
a. applying a sol composition to a metal surface, wherein said composition contains one or more alkoxysilyl group containing compounds, a fluorophore, and a solvent;
b. forming a gelled coating on said surface from said composition;
c. measuring the fluorescence of said coating with a fluorometer, wherein said fluorometer is capable of measuring reflective fluorescence emission measurements;
d. correlating the fluorescence of said coating with the thickness or weight of said coating, and/or with the concentration of alkoxysilyl group containing compound in the coating composition; and
e. optionally applying an additional coating to said metal surface when the thickness of the coating is less than a desired amount or adjusting the concentration of the alkoxysilyl group containing compound applied to said surface.

2. The method of claim 1 wherein said composition contains at least 0.1% by weight of said alkoxysilyl group containing compound relative to the composition.

3. The method of claim 1 wherein said composition contains from about 20 ppb to 20,000 ppm of said fluorophore, relative to alkoxysilyl group containing compound by weight

4. The method of claim 1 wherein said composition contains from about 10 ppm to about 1000 ppm of said fluorophore, relative to the alkoxylsilyl group containing compound by weight.

5. The method of claim 1 wherein said metal contains at least one of the following: aluminum, tin, steel, zinc, titanium, nickel, copper, alloys thereof, and a combination thereof.

6. The method of claim 1 wherein said alkoxysilyl group compound comprises a monfunctional silane or multifunctional silane.

7. The method of claim 6 wherein said compound is monomeric or polymeric.

8. The method of claim 6 wherein said compound is hydrolyzed or unhydrolyzed.

9. The method of claim 1 wherein said fluorophore is selected from the group consisting of: pyrenetetrasulfonate, fluorescein, rhodamine, and derivatives thereof.
